(19) United States
(12) Patent Application Publication
(10) Pub. No.: US 2025/0271002 A1
(43) Pub. Date: Aug. 28, 2025

(54) THREE-AXIS TUNED MASS DAMPER FOR TURBO MOLECULAR PUMP

(71) Applicant: KLA Corporation, Milpitas, CA (US)

(72) Inventors: Tariq Maysarah Ahmed Abuhamdia, San Jose, CA (US); Reynold (Wei-Tse) Lin, Zhubei (TW)

(21) Appl. No.: 18/925,931

(22) Filed: Oct. 24, 2024

Related U.S. Application Data
(60) Provisional application No. 63/558,662, filed on Feb. 28, 2024.

(51) Int. Cl. F04D 29/66; F04D 19/04

(52) U.S. Cl. CPC F04D 29/668; F04D 19/042

(57) ABSTRACT

A mass damper is connected to a vacuum pump to reduce vibrations during operation. The mass damper includes a conic portion defined by a converging end and a diverging end and a damping mass connected to the converging end of the conic portion. The vacuum pump has a pump body, a vacuum inlet in fluid communication with an internal volume of a vacuum chamber, a vacuum outlet, and a rotor assembly disposed within the pump body. The rotor assembly is configured to rotate about a rotary axis to pump gas from the internal volume of the vacuum chamber out of the vacuum outlet. The conic portion may have a cone axis that is coaxial with the rotary axis of the vacuum pump.

### CROSS-REFERENCE TO RELATED APPLICATIONS

This application claims priority to the provisional patent application filed Feb. 28, 2024, and assigned U.S. App. No. 63/558,662, the disclosure of which is hereby incorporated herein by reference.

### FIELD OF THE DISCLOSURE

This disclosure relates to damping systems for vacuum pumps used in semiconductor manufacturing.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a workpiece, such as a semiconductor wafer, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

To minimize environmental factors that can cause defects in the workpiece, manufacturing processes and inspections processes are often performed in controlled environments, such as an enclosed vacuum chamber. Vacuum pressure within the vacuum chamber can be produced using a vacuum pump, such as a turbo molecular pump. These pumps run at high speeds and vibrate, and these vibrations can transfer to the bodies they are attached to within the system. If vibrations are transferred to an inspection system or scanning system, the vibration can reduce accuracy of measurements and produce distorted images. Typical damping systems aim to dampen the connection between the vacuum pump and the vacuum chamber. However, these damping systems may be less effective at high speeds and may be limited to damping along one axis. In order to provide damping along other axes, additional dampers may be used, which increases the complexity and overall mass of the system.

Therefore, what is needed is an improved damping system for a vacuum pump.

### BRIEF SUMMARY OF THE DISCLOSURE

An embodiment of the present disclosure provides a system. The system may comprise a vacuum chamber, a vacuum pump, and a mass damper. The vacuum chamber may include an internal volume. The vacuum pump may have a pump body, a vacuum inlet in fluid communication with the internal volume, a vacuum outlet, and a rotor assembly disposed within the pump body. The rotor assembly may be configured to rotate about a rotary axis to pump gas from the internal volume of the vacuum chamber out of the vacuum outlet. The mass damper may be connected to the vacuum pump. The mass damper may include a conic portion defined by a converging end and a diverging end. The conic portion may have a cone axis that is coaxial with the rotary axis of the vacuum pump, and a damping mass may be connected to the converging end of the conic portion.

In some embodiments, the vacuum pump may be a turbo molecular pump. The rotor assembly may be configured to rotate at a speed of at least 50,000 rpm.

In some embodiments, the vacuum pump may have a vibration frequency of greater than 1 kHz due to rotation of the rotor assembly.

In some embodiments, the mass damper may further include a base portion connected to the vacuum pump. The base portion may surround the diverging end of the conic portion.

In some embodiments, an end surface of the base portion may be flush with the diverging end of the conic portion.

In some embodiments, a plurality of mounting holes may be defined in the base portion. The base portion may be connected to the vacuum pump by a plurality of fasteners extending through the plurality of mounting holes.

In some embodiments, the plurality of mounting holes may be located at rotationally symmetrical positions relative to the cone axis and are parallel to the cone axis.

In some embodiments, a plurality of embossed protrusions may be defined on the end surface of the base portion. Each of the plurality of embossed protrusions may surround one of the plurality of mounting holes.

In some embodiments, a threaded hole may be defined on a planar surface of the damping mass and may be coaxial with the cone axis. The mass damper may further include a tuning mass connected to the damping mass by a fastener received in the threaded hole.

In some embodiments, the conic portion may be hollow.

In some embodiments, the mass damper may further include a cylindrical portion. The damping mass may be connected to the converging end of the conic portion by the cylindrical portion.

In some embodiments, the cylindrical portion may have a diameter that is less than a diameter of the converging end of the conic portion.

In some embodiments, the damping mass may have a diameter that is greater than a diameter of the cylindrical portion.

In some embodiments, the mass damper may be rotationally symmetrical relative to the cone axis.

In some embodiments, the rotary axis of the vacuum pump may be arranged vertically.

In some embodiments, the rotary axis of the vacuum pump may be arranged horizontally.

In some embodiments, the rotary axis of the vacuum pump may be arranged at an oblique angle.

In some embodiments, the vacuum pump may be disposed on top of the vacuum chamber. The mass damper may be disposed on top of the vacuum pump.

In some embodiments, the vacuum pump may be disposed beneath the vacuum chamber. The mass damper may be disposed beneath the vacuum pump.

Another embodiment of the present disclosure provides a method. The method may comprise connecting a vacuum inlet of a vacuum pump to a vacuum chamber. The vacuum pump may include a pump body and a rotor assembly disposed within the pump body, and the rotor assembly may be configured to rotate about a rotary axis. The method may further comprise connecting a mass damper to the vacuum pump. The mass damper may include a conic portion defined by a converging end and a diverging end, the conic portion may have a cone axis that is coaxial with the rotary axis of the vacuum pump, and a damping mass may be connected to the converging end of the conic portion. The method may further comprise driving the rotor assembly to rotate within the pump body to pump gas from an internal volume of the vacuum chamber out of a vacuum outlet.

### DESCRIPTION OF THE DRAWINGS

For a fuller understanding of the nature and objects of the disclosure, reference should be made to the following detailed description taken in conjunction with the accompanying drawings, in which:

FIG. 1 is a side view of a system according to an embodiment of the present disclosure;

FIG. 2 is a top view of a mass damper of a system according to an embodiment of the present disclosure;

FIG. 3 is a section view along line A-A of the mass damper of FIG. 2;

FIG. 4 is a section view along line B-B of the mass damper of FIG. 2;

FIG. 5 is another section view along line A-A of the mass damper of FIG. 2, where a tuning mass is connected to the damping mass;

FIG. 6 is another section view along line B-B of the mass damper of FIG. 2, where a tuning mass is connected to the damping mass;

FIG. 7 is a top perspective view of a mass damper according to another embodiment of the present disclosure;

FIG. 8 is a bottom perspective view of the mass damper of FIG. 7;

FIG. 9 is a side view of a system according to another embodiment of the present disclosure, where the vacuum pump is arranged vertically beneath the vacuum chamber;

FIG. 10 is a side view of a system according to another embodiment of the present disclosure, where the vacuum pump is arranged horizontally next to the vacuum chamber;

FIG. 11 is a side view of a system according to another embodiment of the present disclosure, where the vacuum pump is arranged at an oblique angle next to the vacuum chamber; and

FIG. 12 is a flowchart of a method according to an embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

An embodiment of the present disclosure provides a system 100. The system 100 may be, for example, an inspection system or a metrology system configured inspect or measure one or more properties of a workpiece. The workpiece may be, for example, a semiconductor wafer, substrate, printed circuit board (PCB), flat panel display (FPD), integrated circuit (IC), or other type of workpiece.

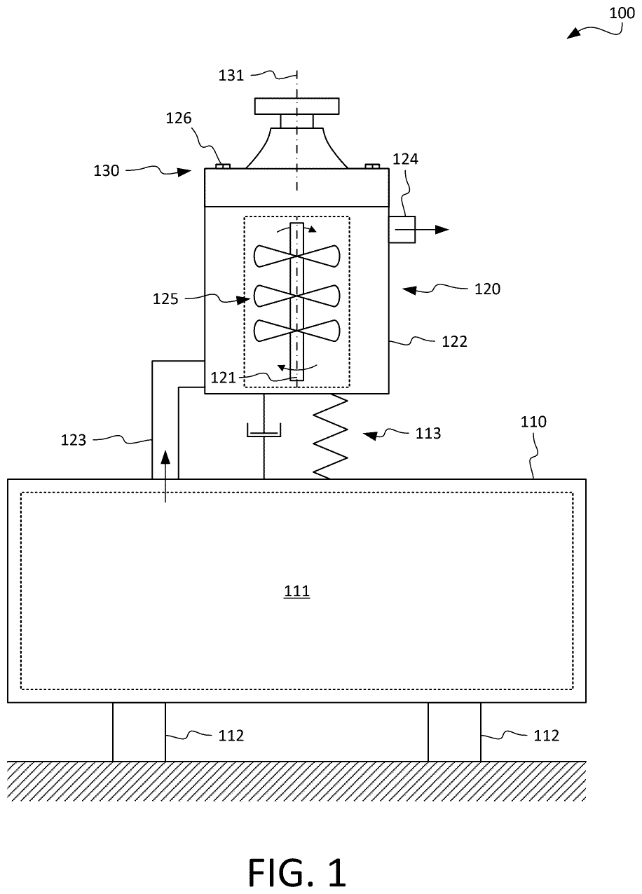

The system 100 may comprise a vacuum chamber 110, as shown in FIG. 1. The vacuum chamber 110 may define an internal volume 111, in which one or more inspection or metrology processes may be performed on the workpiece. The vacuum chamber 110 may be supported by one or more air mounts 112, which can reduce vibration transfer from the environment to the vacuum chamber 110.

The system 100 may further comprise a vacuum pump 120. The vacuum pump 120 may have a pump body 122, a vacuum inlet 123 in fluid communication with the internal volume 111 of the vacuum chamber 110, a vacuum outlet 124, and a rotor assembly 125 disposed within the pump body 122. The rotor assembly 125 may be configured to rotate about a rotary axis 121. The rotor assembly 125 may include a rotatable shaft driven by a motor and a plurality of rotor blades connected to the shaft. The vacuum pump 120 may further include a plurality of stator blades within the pump body 122, and the plurality of rotor blades may be configured to rotate relative to the plurality of stator blades. Rotation of the rotor assembly 125 (i.e., the shaft and the plurality of rotor blades) may pump gas from the internal volume 111 of the vacuum chamber 110 (via the vacuum inlet 123) through the pump body 122 and out of the vacuum outlet 124. Accordingly, the vacuum pump 120 may be configured to produce a vacuum pressure within the internal volume 111 of the vacuum chamber 110. In some embodiments, the vacuum pressure may be high vacuum pressure (1×10⁻³ to 1×10⁻⁹ Torr) or ultra-high vacuum pressure (1×10⁻⁹ to 1×10⁻¹² Torr). The vacuum pump 120 may be connected to the vacuum chamber 110 by a suspension assembly 113.

The suspension assembly 113 may include one or more springs and/or dampers configured to reduce transmission of vibrations from the vacuum pump 120 to the vacuum chamber 110. The suspension assembly 113 may be built-in with the structure of the vacuum pump 120 or may be a separate element provided between the vacuum pump 120 and the vacuum chamber 110.

In some embodiments, the vacuum pump 120 may be a turbo molecular pump. The rotor assembly 125 may be configured to rotate at a speed of at least 50,000 rpm to produce the vacuum pressure. At these speeds, the vacuum pump 120 may have a vibration frequency of greater than 1 kHz due to the rotation of the rotor assembly 125. In some embodiments, the vacuum pump 120 may have a vibration frequency for greater than 2 kHz due to the rotation of the rotor assembly 125. In an instance, the vibration frequency may be 3.2 kHz or more. At these vibration frequencies, the suspension assembly 113 may be unable to effectively reduce transmission of vibrations from the vacuum pump 120 to the vacuum chamber 110. In addition, due to the rotation of the rotor assembly 125, the vibration may induce movement of the vacuum pump 120 along three axes (i.e., the rotary axis 121 and two axes orthogonal to the rotary axis 121), which may be difficult for the suspension assembly 113 to compensate for.

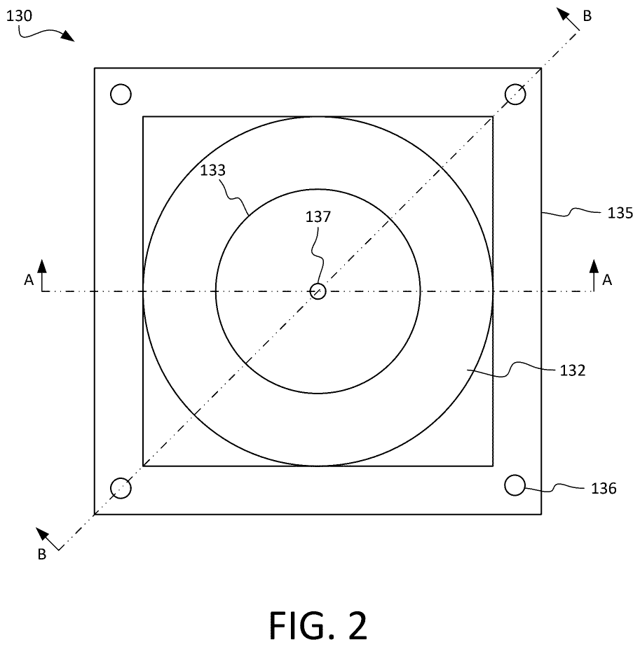

The system 100 may further comprise a mass damper 130. The mass damper 130 may be connected to the vacuum pump 120 and may reduce the vibration in the system 100 generated by the vacuum pump 120. Referring to FIGS. 2-8, the mass damper 130 may include a conic portion 132 defined by a converging end 132a and a diverging end 132b. The conic portion 132 may be a frustoconical shape having a curved or tapered profile from the converging end 132a to the diverging end 132b. In some embodiments, the conic portion 132 may be hollow. For example, the conic portion 132 may include a hollow volume 132c, which can be open to the diverging end 132b. The conic portion 132 may have a cone axis 131 that is coaxial with the rotary axis 121 of the vacuum pump 120. The mass damper 130 may be rotationally symmetrical relative to the cone axis 131. The mass damper 130 may further include a damping mass 133 connected to the converging end 132a of the conic portion 132. In some embodiments, the damping mass 133 may be removably connected to the conic portion 132. The damping mass 133 may have a cylindrical shape. The damping mass 133 may be integrally formed with the conic portion 132, or the damping mass 133 may be a separate element connected to the conic portion 132.

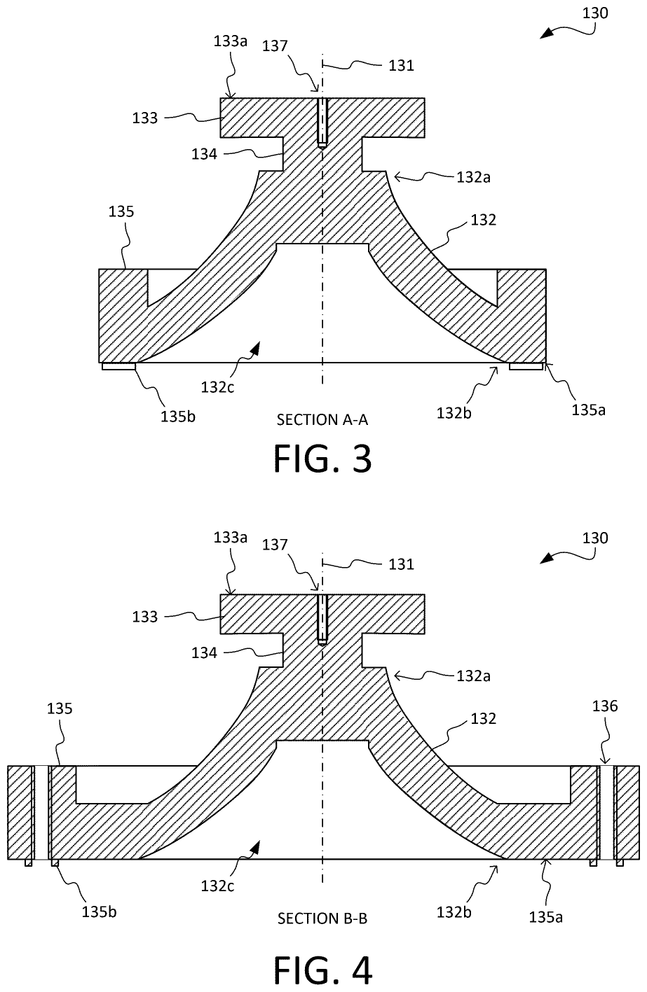

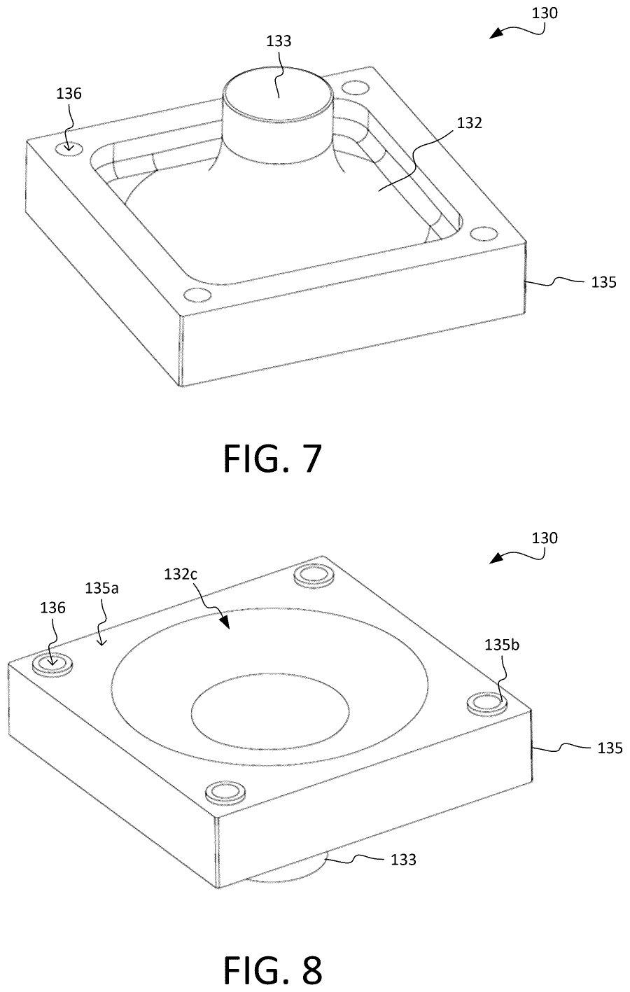

In some embodiments, the mass damper 130 may further include a cylindrical portion 134. The damping mass 133 may be connected to the converging end 132a of the conic portion 132 by the cylindrical portion 134. As shown in FIG. 3 and FIG. 4, the cylindrical portion 134 may have a diameter that is less than a diameter of the converging end 132a of the conic portion 132. In some embodiments, the damping mass 133 may have a diameter that is greater than the diameter of the cylindrical portion 134. In some embodiments, the damping mass 133 may be directly connected to the converging end 132a of the conic portion 132, without a cylindrical portion 134 disposed therebetween (as shown in FIG. 7 and FIG. 8).

In some embodiments, the mass damper 130 may further include a base portion 135. The base portion 135 may surround the diverging end 132b of the conic portion 132. For example, an end surface 135a of the base portion 135 may be flush with the diverging end 132b of the conic portion. The base portion 135 may connect the mass damper 130 to the vacuum pump 120. For example, the end surface 135a of the base portion 135 may be disposed on the pump body 122 of the vacuum pump 120. The shape of the base portion 135 may depend on the shape of the pump body 122. For example, as shown in FIG. 2, the base portion 135 may have a substantially square shape. However, in some embodiments, the base portion 135 may have a substantially circular shape or other shapes. A plurality of mounting holes 136 may be defined in the base portion 135, and the base portion 135 may be connected to the vacuum pump 120 by a plurality of fasteners 126 extending through the plurality of mounting holes 136. The number and arrangement of the plurality of mounting holes 136 of the base portion may depend on the corresponding structure of the pump body 122 of the vacuum pump 120. The plurality of mounting holes 136 may be located at rotationally symmetrical positions relative to the cone axis 131 (as shown in FIG. 2) and may be parallel to the cone axis 131 (as shown in FIG. 4).

In some embodiments, a plurality of embossed protrusions 135b may extend from the end surface 135a of the base portion 135. The plurality of embossed protrusions 135b may be ring-shaped and surround the plurality of mounting holes 136. The plurality of embossed protrusions 135b may be received in corresponding recesses of the vacuum pump 120, so as to align the mass damper with the vacuum pump 120 for insertion of the plurality of fasteners 126 through the plurality of mounting holes 136 and precisely define the boundary conditions of the mass damper 130. With the plurality of embossed protrusions 135b received in the recesses of the vacuum pump 120, relative rotation between the mass damper 130 and the vacuum pump 120 can be prevented or minimized.

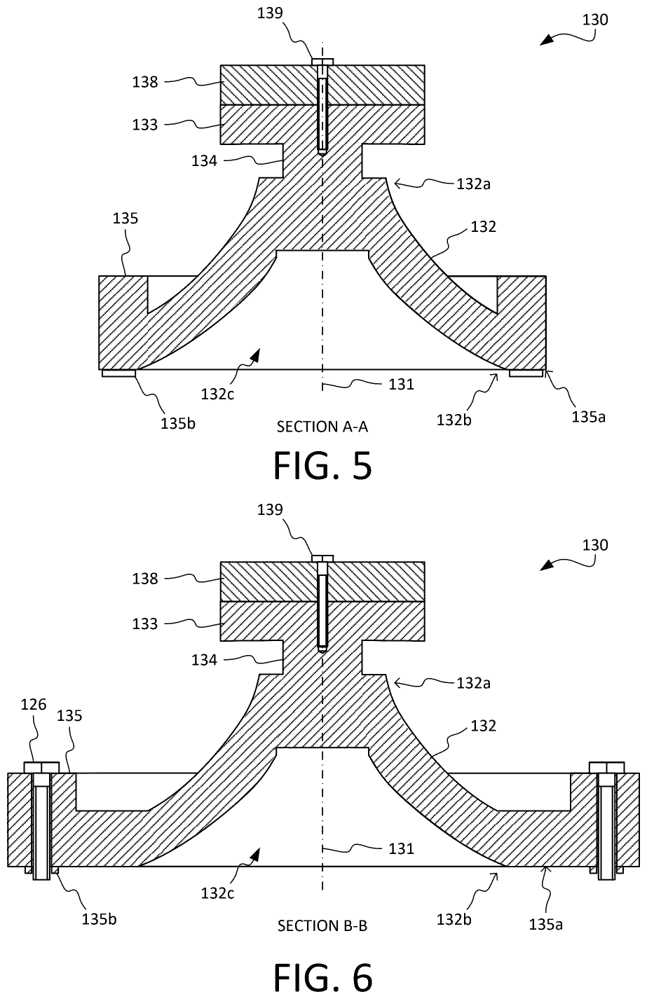

In some embodiments, a threaded hole 137 may be defined on a planar surface 133a of the damping mass 133. The threaded hole 137 may be coaxial with the cone axis 131. The mass damper 130 may further include a tuning mass 138 connected to the damping mass 133 by a fastener 139 receiving in the threaded hole 137, as shown in FIG. 5 and FIG. 6. The tuning mass 138 may have a cylindrical shape. The tuning mass 138 may be configured to increase the overall mass of the mass damper 130 and may adjust the location of the center of mass of the mass damper 130 to further reduce vibrations generated by the vacuum pump 120. In some embodiments, the tuning mass 138 may have the same dimensions as the damping mass 133. Alternatively, the tuning mass 138 may have different dimensions (e.g., diameter and/or thickness) for fine adjustment of the overall mass and the center of mass of the mass damper 130. For example, a thicker tuning mass 138 may move the center of mass of the mass damper 130 along the cone axis 131 compared to a larger diameter tuning mass 138 of the same mass.

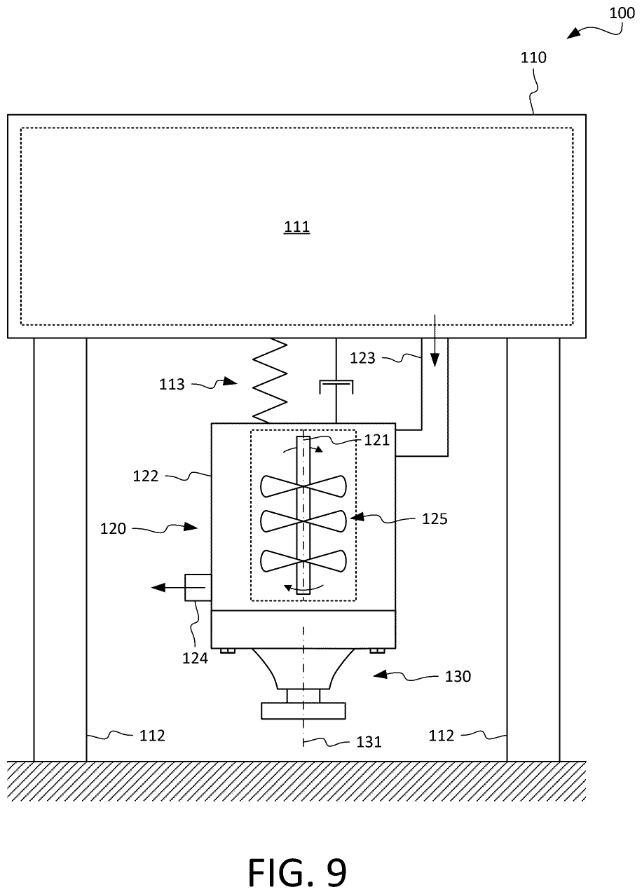

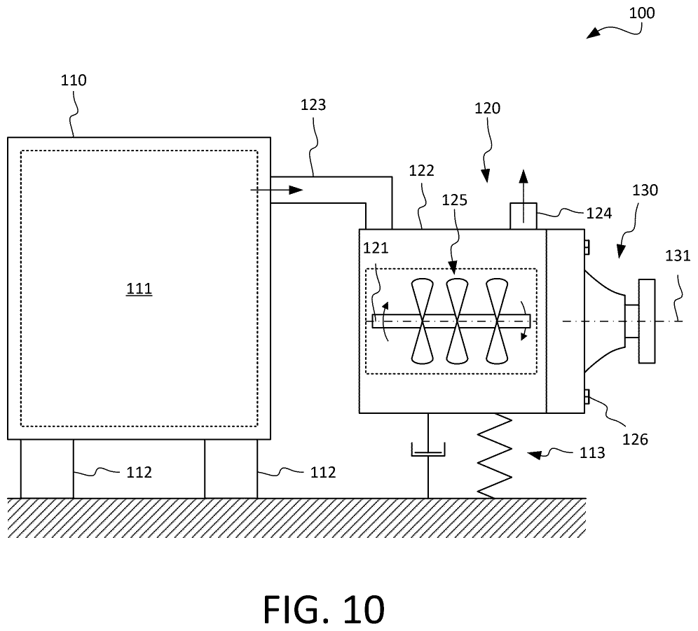

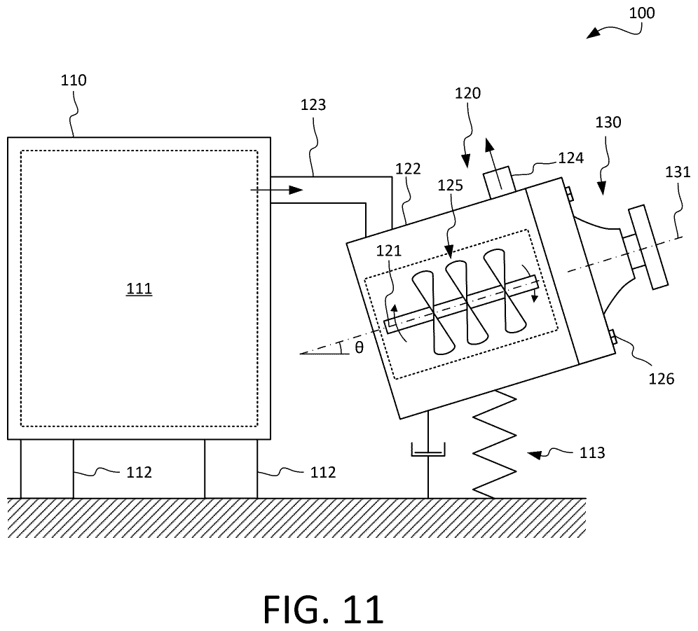

Based on the rotationally symmetrical design of the mass damper 130 and its specifically tuned overall mass and center of mass, the mass damper 130 can reduce the vibration in the system 100 generated by the vacuum pump 120 in various orientations. For example, the vacuum pump 120 can be arranged on top of the vacuum chamber 110 with the rotary axis 121 arranged vertically, and the mass damper 130 can be arranged on top of the vacuum pump 120, as shown in FIG. 1. Alternatively, the vacuum pump can be arranged beneath the vacuum chamber 110 with the rotary axis 121 arranged vertically, and the mass damper 130 can be disposed beneath the vacuum pump 120, as shown in FIG. 9. In some embodiments, the vacuum pump 120 can be arranged adjacent to the vacuum chamber 110, with different orientations of the rotary axis 121. For example, the rotary axis 121 may be arranged horizontally (as shown in FIG. 10) or at an oblique angle θ (as shown in FIG. 11). The oblique angle θ may be an angle between 0° and 90°. In an instance, the oblique angle Γ may be 45°. In any arrangement of the vacuum pump 120 relative to the vacuum chamber 110 and arrangement of the rotary axis 121, the cone axis 131 of the mass damper 130 may be coaxial with the rotary axis 121, such that the mass damper 130 provides three-axis vibration damping for the vacuum pump 120.

With the system 100, the vibrations generated by the vacuum pump 120 can be reduced (e.g., by 40% to 90%) by simply attaching the mass damper 130 to the vacuum pump 120. While the structure of the mass damper 130 is designed for specific operating speeds of the vacuum pump 120, the mass damper 130 can be tuned for different operating speeds by connecting an additional tuning mass 138 to the damping mass 133 of the mass damper 130. Accordingly, the mass damper 130 can effectively reduce transmission of vibrations from the vacuum pump 120 to the vacuum chamber 110, which can improve accuracy of measurements and image quality of inspection and metrology systems provided in the vacuum chamber 110.

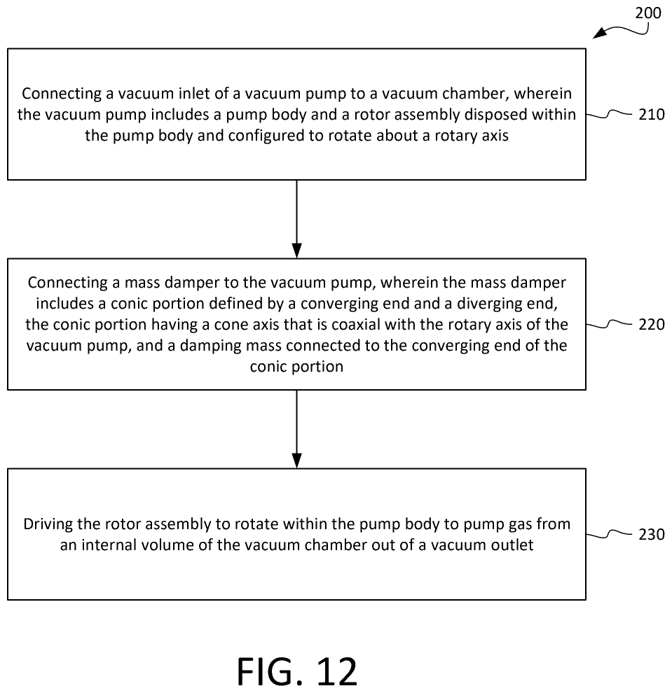

Another embodiment of the present disclosure provides a method 200. As shown in FIG. 12, the method 200 may comprise the following steps.

At step 210, a vacuum inlet of a vacuum pump is connected to a vacuum chamber. The vacuum pump may include a pump body and a rotor assembly disposed within the pump body and configured to rotate about a rotary axis.

At step 220, a mass damper is connected to the vacuum pump. The mass damper may include a conic portion defined by a converging end and a diverging end. The conic portion may have a cone axis that is coaxial with the rotary axis of the vacuum pump. A damping mass may be connected to the converging end of the conic portion. The structure of the damping mass may be designed to reduce vibrations generated by the vacuum pump at specific operating speeds of the vacuum pump.

In some embodiments, the first vibration resonance frequency of the mass damper may be measured and compared to the running frequency of the vacuum pump. If there is a large difference between the frequencies, the damping mass can be removed or additional tuning masses can be added or removed from the mass damper. The tuning mass may be configured to modify the overall mass and the center of mass of the mass damper, so as to reduce vibrations generated by the vacuum pump at different operating speeds. For example, an iterative process of adding or removing tuning masses to the mass damper and measuring the vibrations transmitted to the system can be performed until the first resonance of the mass damper matches the vacuum pump running frequency.

At step 230, the rotor assembly is driven to rotate within the pump body to pump gas from an internal volume of the vacuum chamber out of a vacuum outlet.

With the method 200, the vibrations generated by the vacuum pump can be reduced (e.g., by 60% to 90%) by simply attaching the mass damper to the vacuum pump. While the structure of the mass damper is designed for specific operating speeds of the vacuum pump, the mass damper can be tuned for different operating speeds by connecting an additional tuning mass to the damping mass of the mass damper. Accordingly, the mass damper can effectively reduce transmission of vibrations from the vacuum pump to the vacuum chamber, which can improve accuracy of measurements and image quality of inspection and metrology systems provided in the vacuum chamber.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a vacuum chamber including an internal volume;
a vacuum pump having a pump body, a vacuum inlet in fluid communication with the internal volume, a vacuum outlet, and a rotor assembly disposed within the pump body and configured to rotate about a rotary axis to pump gas from the internal volume of the vacuum chamber out of the vacuum outlet; and
a mass damper connected to the vacuum pump, wherein the mass damper includes a conic portion defined by a converging end and a diverging end, the conic portion having a cone axis that is coaxial with the rotary axis of the vacuum pump, and a damping mass connected to the converging end of the conic portion.

2. The system of claim 1, wherein the vacuum pump is a turbo molecular pump, and the rotor assembly is configured to rotate at a speed of at least 50,000 rpm.

3. The system of claim 1, wherein the vacuum pump has a vibration frequency of greater than 1 kHz due to rotation of the rotor assembly.

4. The system of claim 1, wherein the mass damper further includes a base portion connected to the vacuum pump, the base portion surrounding the diverging end of the conic portion.

5. The system of claim 4, wherein an end surface of the base portion is flush with the diverging end of the conic portion.

6. The system of claim 4, wherein a plurality of mounting holes are defined in the base portion, and the base portion is connected to the vacuum pump by a plurality of fasteners extending through the plurality of mounting holes.

7. The system of claim 6, wherein the plurality of mounting holes are located at rotationally symmetrical positions relative to the cone axis and are parallel to the cone axis.

8. The system of claim 6, wherein a plurality of embossed protrusions are defined on an end surface of the base portion, and each of the plurality of embossed protrusions surrounds one of the plurality of mounting holes.

9. The system of claim 1, wherein a threaded hole is defined on a planar surface of the damping mass and is coaxial with the cone axis, and the mass damper further includes a tuning mass connected to the damping mass by a fastener received in the threaded hole.

10. The system of claim 1, wherein the conic portion is hollow.

11. The system of claim 1, wherein the mass damper further includes a cylindrical portion, and the damping mass is connected to the converging end of the conic portion by the cylindrical portion.

12. The system of claim 11, wherein the cylindrical portion has a diameter that is less than a diameter of the converging end of the conic portion.

13. The system of claim 11, wherein the damping mass has a diameter that is greater than a diameter of the cylindrical portion.

14. The system of claim 1, wherein the mass damper is rotationally symmetrical relative to the cone axis.

15. The system of claim 1, wherein the rotary axis of the vacuum pump is arranged vertically.

16. The system of claim 1, wherein the rotary axis of the vacuum pump is arranged horizontally.

17. The system of claim 1, wherein the rotary axis of the vacuum pump is arranged at an oblique angle.

18. The system of claim 1, wherein the vacuum pump is disposed on top of the vacuum chamber, and the mass damper is disposed on top of the vacuum pump.

19. The system of claim 1, wherein the vacuum pump is disposed beneath the vacuum chamber, and the mass damper is disposed beneath the vacuum pump.

20. A method comprising:
connecting a vacuum inlet of a vacuum pump to a vacuum chamber, wherein the vacuum pump includes a pump body and a rotor assembly disposed within the pump body and configured to rotate about a rotary axis;
connecting a mass damper to the vacuum pump, wherein the mass damper includes a conic portion defined by a converging end and a diverging end, the conic portion having a cone axis that is coaxial with the rotary axis of the vacuum pump, and a damping mass connected to the converging end of the conic portion; and
driving the rotor assembly to rotate within the pump body to pump gas from an internal volume of the vacuum chamber out of a vacuum outlet.
